(19) United States
(12) Patent Application Publication
(10) Pub. No.: US 2021/0057888 A1
(43) Pub. Date: Feb. 25, 2021

(54) STRUCTURED LIGHT PROJECTION SYSTEM INCLUDING NARROW BEAM DIVERGENCE SEMICONDUCTOR SOURCES

(71) Applicant: Princeton Optronics, Inc., Mercerville, NJ (US)

(72) Inventors: Jean-Francois Seurin, Eindhoven (NL); Chuni Ghosh, Eindhoven (NL); Robert Van Leeuwen, Eindhoven (NL)

(21) Appl. No.: 16/957,854

(22) PCT Filed: Dec. 27, 2018
(86) PCT No.: PCT/US2018/067593

§ 371 Date: Jun. 25, 2020

Related U.S. Application Data
(60) Provisional application No. 62/611,159, filed on Dec. 28, 2017.

(51) Int. Cl. H01S 5/42; H01S 5/042; H01S 5/183; H01S 5/40

(52) U.S. Cl. CPC H01S 5/423; H01S 5/0421; H01S 2301/163; H01S 5/18377; H01S 5/4031; H01S 5/18369

(57) ABSTRACT

Structured light projection system include narrow beam divergence semiconductor sources. The structured light projector system includes an array of narrow beam divergence semiconductor sources, and a projection lens operable to generate an image of the array of narrow beam divergence semiconductor source. Each narrow beam divergence semiconductor source can include an extended length mirror that helps suppress one or more longitudinal and/or transverse modes such that the beam divergence and/or the spectral width of emission is substantially reduced.

### CROSS-REFERENCE TO RELATED APPLICATION(S)

The present application claims the benefit of priority of U.S. Provisional Patent Application No. 62/611,159 filed on Dec. 28, 2017, the contents of which are incorporated by reference herein in their entirety.

### FIELD OF THE DISCLOSURE

The present disclosure relates to narrow beam divergence semiconductor sources and their incorporation into structured light projection systems.

### BACKGROUND

Structured light projection systems can be used, for example, to obtain depth and surface information of objects in the scene. Such systems sometimes use light emitting devices such as vertical-cavity surface-emitting lasers (VCSELs). A vertical-cavity surface-emitting laser (VCSEL) is a semiconductor-based laser diode that can emit a highly efficient optical beam vertically, for example, from its top surface. In VCSELs, high reflectivity mirrors are generally required. The high reflectivity mirrors can be implemented, for example, as distributed Bragg reflectors (DBR) (e.g., quarter-wave-thick layers of alternating high and low refractive indexes), made of semiconductor or dielectric material. To achieve a high reflectivity with a reasonable number of layers, a high index contrast is provided (e.g., a high-contrast DBR). However, use of high-contrast DBR can generate a broad stop-band and, in the case of VCSELs with a long internal monolithic cavity, this will allow multiple longitudinal modes to lase. The longitudinal modes can, in some applications, give rise to undesirable or unstable operation (e.g., “kinks” in the power versus current curve; mode-hoping).

### SUMMARY

The present disclosure describes narrow beam divergence semiconductor sources and their integration into structured light projection systems.

For example, in one aspect, a structured light projector includes an array of narrow beam divergence semiconductor sources, each narrow beam divergence semiconductor source within the array being operable to generate a beam with a substantially narrow beam divergence and substantially uniform beam intensity. Multiple electrical contacts are operable to direct electric current to the array of narrow beam divergence semiconductor sources. A projection lens is operable to generate an image of the array of narrow beam divergence semiconductor source.

Each of the narrow beam divergence semiconductor sources can include an extended length mirror (also referred to sometimes as a hybrid mirror) that can help suppress one or more longitudinal and/or transverse modes such that the beam divergence and/or the spectral width of emission is substantially reduced.

Some implementations include one or more of the following features. For example, each narrow beam divergence semiconductor source can include an optical resonant cavity including a high reflection mirror having first and second sides, an extended length mirror having first and second sides, and an active region. The high reflection mirror and the extended length mirror can be disposed on distal sides of the active region such that the first side of the high reflection mirror is coupled to a first side of the active region and the first side of the extended length mirror is coupled to a second side of the active region opposing the first. Electrical contacts are operable to direct electric current to the active region. The extended length mirror and the high reflection mirror can be operable to suppress one or more longitudinal and/or transverse modes. In some implementations, only one longitudinal mode lases.

The array can include any of various types of narrow beam divergence semiconductor sources including, for example, VCSELs, VECSELs, LEDs and RC-LEDs, and edge-emitting lasers, such as those described in greater detail below.

Other aspects, features and various advantages will be readily apparent fro the following detailed description, the accompanying drawings, and the claims.

### BRIEF DESCRIPTION OF THE DRAWINGS

FIG. 1 illustrates an example of a top-emitting VCSEL structure.

FIG. 2 illustrates another example of a top-emitting VCSEL structure.

FIG. 3 illustrates an example of a bottom-emitting VCSEL structure.

FIG. 4 illustrates an example of a VECSEL structure.

FIG. 5 illustrates an example of a LED structure.

FIG. 6 illustrates an example of a RC-LED structure.

FIG. 7 illustrates an example of an edge-emitting laser.

FIG. 8 illustrates an example of a structured light projection system.

### DETAILED DESCRIPTION

The present disclosure describes VCSELs having low divergence and/or operable for high single-mode power in some cases. In particular, a hybrid mirror is provided by combining a narrow bandwidth mirror with a high-reflectivity mirror, such that the narrow bandwidth mirror is place within the laser cavity (i.e., between two high-reflectivity mirrors). Preferably, the narrow bandwidth mirror has a sufficiently large penetration depth to achieve the desired diffraction losses of higher order transverse modes, and has a narrow enough stop-band to filter out unwanted modes. The reflectivity of the high-reflectivity mirror should be insufficient by itself for the laser to achieve lasing. There should be an adequate phase matching layer between the two mirrors for constructive interference. The combined reflectivity at the designed wavelength (peak reflectivity) is sufficient for the laser to achieve lasing.

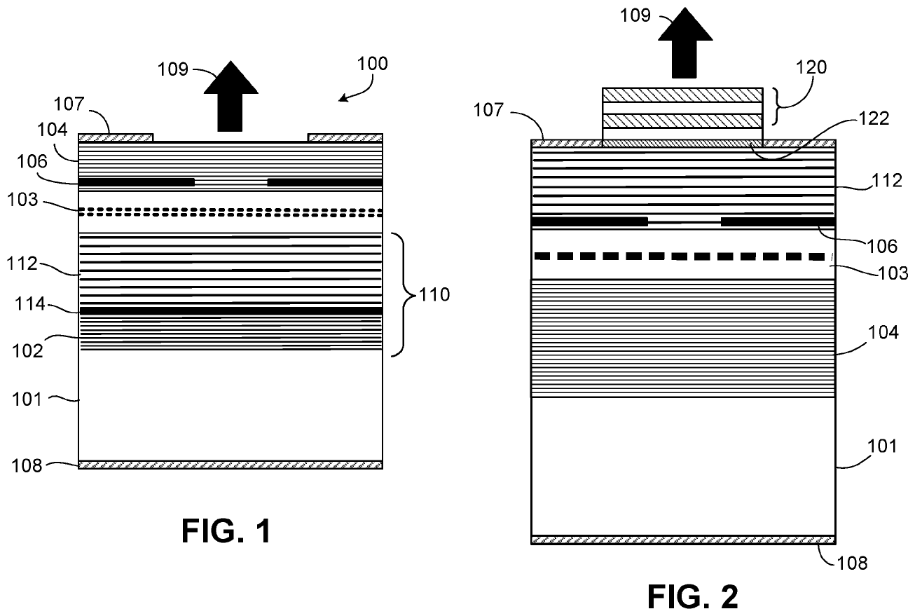

As shown in FIG. 1, a top-emitting VCSEL device 100 includes a substrate 101 (e.g., a N—GaAs substrate) on which epitaxial layers for the VCSEL structure are grown, for example, by a metal-organic chemical vapor deposition (MOCVD) or other deposition process. The optical resonant laser cavity of the VCSEL is formed by a hybrid mirror 110 and a distributed Bragg grating (DBR) partial-reflectivity top mirror 104 to allow for emission of the VCSEL beam 109. The hybrid mirror 110 can be achieved by combining a narrow bandwidth mirror 112 (e.g., a low-contrast N-DBR) with a high-reflectivity (e.g., 100%) bottom mirror 102, such that the narrow bandwidth mirror 112 is placed within the laser cavity (i.e., between the two relatively high-reflectivity mirrors 102, 104). The bottom mirror 102 can be implemented, for example, as a high-contrast N-DBR. One or more phase-matching layers 114 can be provided between the bottom mirror 102 and the narrow bandwidth mirror 112. The top mirror 104 can be implemented, for example, as a high-contrast P-DBR.

A gain section 103, which may be referred to as an active section and can include quantum wells, is disposed between the hybrid reflector 110 and the top reflector 104. A current aperture 106 confines the current in the center region of the VCSEL device 100 to activate the quantum wells to produce optical gain and to generate a laser cavity mode in the VCSEL laser cavity. In the top-emitting VCSEL device illustrated in FIG. 1, the output beam 109 is taken out of the partial-reflectivity top mirror 104.

The VCSEL device 100 is activated by applying current through an anode and cathode electrical connections 107, 108, which can be implemented, for example, as metal contacts. The presence of the low-contrast DBR in the hybrid mirror 110 increases the effective length of the optical resonant cavity such that multiple longitudinal modes are present. Thus, the hybrid mirror 110 also may be referred to as an extended length mirror. Because of the effective narrower bandwidth of the hybrid mirror 110, the additional, unwanted longitudinal modes have much higher round-trip losses compared to the main mode and, thus, the longitudinal modes do not achieve lasing. Thus, the hybrid mirror 110 and the high reflection mirror 104 are operable to provide mode filtering by suppressing one or more longitudinal and/or transverse modes. Preferably, in some implementations, only one longitudinal mode lases.

Various details of the hybrid mirror 110 can vary depending on the implementation. Nevertheless, in a particular example, the hybrid mirror 110 can be composed of the following layers: a low-contrast N-DBR layer 112 having a thickness in a range of 4 μm-15 μm, and a refractive index difference Δn/n in the range of 1%-7%; a N-phase matching layer 114 having a quarter wavelength optical thickness, and an index of refraction n of about 3.5; and a high-contrast N-DBR mirror 102 having a thickness in a range of 2 μm-4 μm, and refractive index difference Δn/n in the range of 10%-20%. Some or all of the foregoing values may differ for other implementations.

In some instances, the extended length mirror has an effective penetration depth extending multiple emission wavelength distances from the first side of the extended length mirror. For example, the effective penetration depth of the extended length mirror extends, in some cases, between 46-116 emission wavelength distances. In some cases, the penetration depth of the extended length mirror is between 6-15 μm, the emission wavelength is between 700-1064 nm, and the relative refractive index difference is between 1-7%. In some instances, the penetration depth of the high reflection mirror is between 2-4 μm, the emission wavelength is between 700-1064 nm, and the relative refractive index difference is between 10-20%.

In some instances, the high reflection mirror has an effective penetration depth extending multiple emission wavelength distances from the first side of the high reflection mirror. In some cases, the effective penetration depth of the high reflection mirror extends between 15-30 emission wavelength distances

In some implementations, the full-width half-maximum (FWHM) intensity divergence angle is less than 10 degrees.

Some implementations include additional features to enhance operation. For example, as shown in FIG. 2, the VCSEL device includes a high-contrast dielectric mirror coating 120 on top of a phase matching layer 122 and a low-contrast mirror 112.

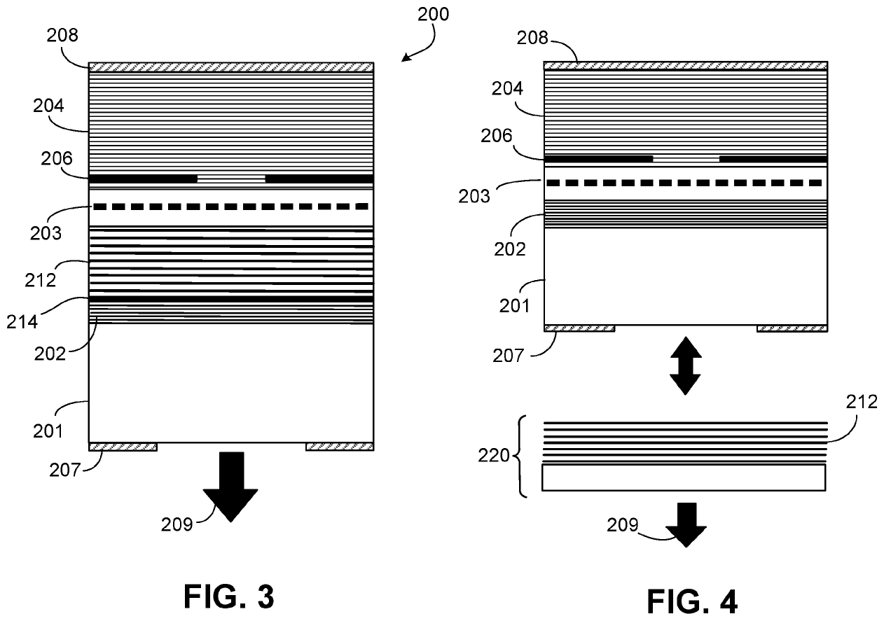

A hybrid mirror as described above also can be integrated into a bottom-emitting VCSEL 200 as shown in the example of FIG. 3. The VCSEL device 200 includes a substrate 201 (e.g., a N—GaAs substrate) on which epitaxial layers for the VCSEL structure are grown. The optical resonant laser cavity of the VCSEL is formed by a hybrid mirror 210 and a distributed Bragg grating (DBR) high-reflectivity top mirror 104 (e.g., 100%). The hybrid mirror 110 can be achieved by combining a narrow bandwidth mirror 212 (e.g., a low-contrast N-DBR) with the partial-reflectivity bottom mirror 202, such that the narrow bandwidth mirror 212 is placed within the laser cavity (i.e., between the two relatively high-reflectivity mirrors 202, 204). The bottom mirror 202 in this case is partially reflecting so as to allow for emission of the VCSEL beam 109. The bottom mirror 202 can be implemented, for example, as a high-contrast N-DBR. One or more phase-matching layers 214 can be provided between the bottom mirror 202 and the narrow bandwidth mirror 212. The top mirror 204 can be implemented, for example, as a high-contrast P-DBR.

The gain section 203, which can include quantum wells, is disposed between the hybrid mirror 210 and the top mirror 204. A current aperture 206 confines the current in the center region of the VCSEL device 200 to activate the quantum wells to produce optical gain and to generate a laser cavity mode in the VCSEL laser cavity. The VCSEL device 200 is activated by applying current through an anode and cathode electrical connections 207, 208, which can be implemented, for example, as metal contacts. In the bottom-emitting VCSEL device illustrated in FIG. 3, the output beam 209 is taken out of the partial-reflectivity bottom mirror 202.

As with the top-emitting VCSEL, the bottom-emitting VCSEL 200 is operable to provide mode filtering by suppressing one or more longitudinal and/or transverse modes. Preferably, in some implementations, only one longitudinal mode lases.

A low-contrast mirror can be used with other device such as vertical external-cavity surface-emitting lasers (VECSELs) as well, light emitting diodes (LEDs) and RC-LEDs. FIGS. 4-6 illustrate examples.

As shown in the example of FIG. 4, a low-contrast mirror 212 is provided on the external mirror 220 of a VECSEL. The low-contrast mirror 212 can be implemented, for example, using a shallow contrast dielectric coating.

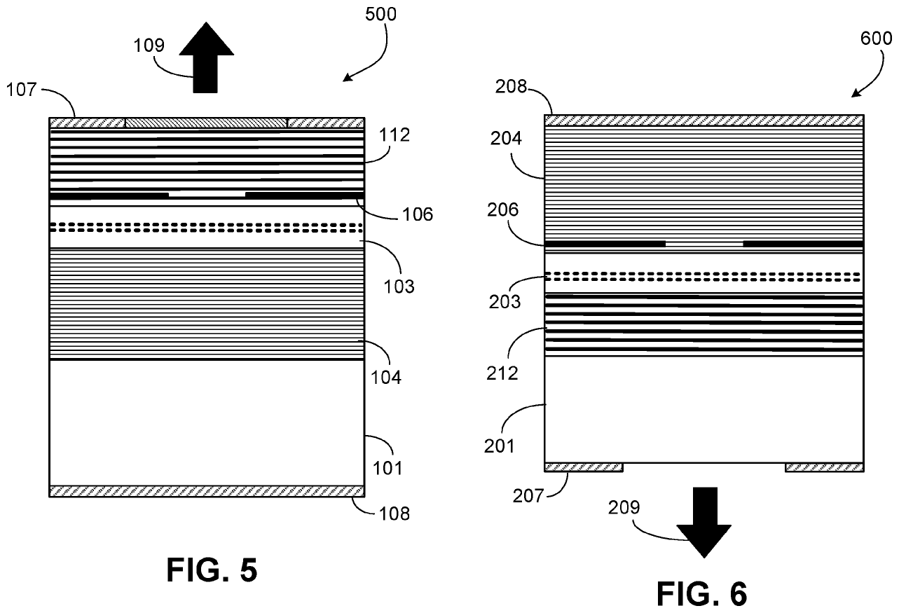

Similarly, FIG. 5 shows an example of a LED 500 that includes a low-contrast mirror 112, and FIG. 6 shows an example of a RC-LED 600 that includes a low-contrast mirror 212.

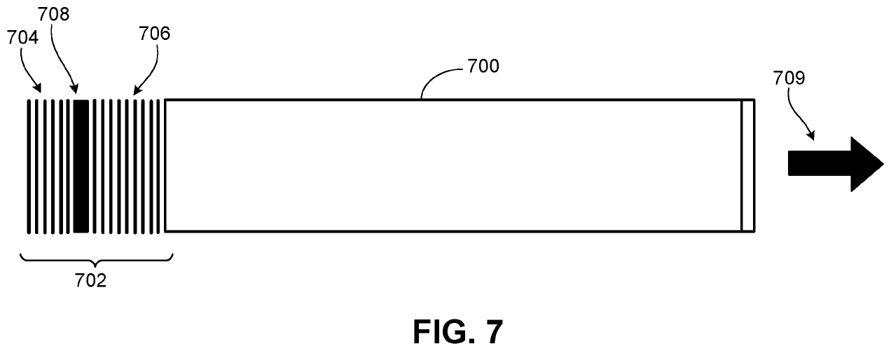

Although the foregoing examples illustrate incorporation of a low-contrast mirror 112 or 212 onto vertically emitting devices, the techniques also can be used in connection with edge-emitting devices (e.g., edge-emitting lasers). As illustrated in FIG. 7, a narrow beam divergence semiconductor optical edge-emitting laser 700 includes a hybrid mirror (e.g., a hybrid DBR) 702. The hybrid DBR has first and second sides, the edge-emitting laser 700 being disposed on the first side of the hybrid DBR 702. The hybrid DBR 702 includes a high-contrast region 704 and a low-contrast region 706. The high-contrast region 704 includes multiple high refractive index difference pairs of DBR materials of a second charge-carrier type, the high-contrast pairs being periodically disposed within the high-contrast region. The low-contrast region 706 includes multiple pairs of low refractive index difference DBR materials of the second charge-carrier type, the low-contrast pairs being periodically disposed within the low-contrast region. The hybrid DBR 702 can include one or more phase-matching layers 708 disposed between the high-contrast region 704 and the low-contrast region 706. The hybrid DBR also can include a backside dielectric coating disposed on the second side of the hybrid DBR. The hybrid DBR 702 and the edge-emitting laser 700 are operable in combination to generate a spectral bandwidth of emission 709, where one or more transverse and/or longitudinal modes are substantially suppressed such that the beam divergence and/or the spectral width of emission is substantially reduced.

The VCSELs and other light emitting devices described here can be used for applications such as compact, high-sensitivity LIDAR time-of-flight (TOF) systems and optical, high-bandwidth communications for high-speed data links. Examples of such applications include measuring short distances in self-driving automobiles and other proximity sensing applications. The devices also can be incorporated into three-dimensional sensing and gesture recognition, for example, in gaming and mobile devices. Further, in data-link applications, replacing low bandwidth data optoelectronics with higher bandwidth can enable existing fiber links to be upgraded at relatively low cost without the need to add fiber infrastructure.

In some applications, multiple narrow beam divergence semiconductor sources such as those described above can be integrated into an illumination system. For example, an array of narrow beam divergence semiconductor sources (e.g., VCSELs) as described above can be used for structured light projection in which a known optical pattern is projected onto a scene. Structured light projection systems can be used, for example, to obtain depth and surface information of objects in the scene.

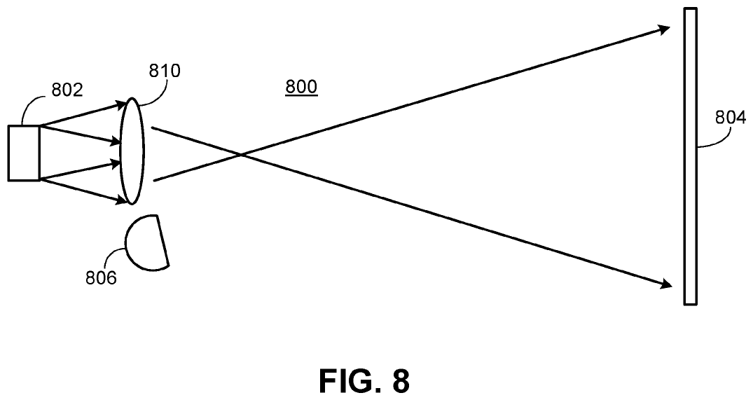

As shown in the example of FIG. 8, a structured light illumination system 800 includes an array 802 of VCSELs (such as those described in connection with any of FIGS. 1-3), and is operable to project an image composed of a structured light pattern 804. The projected pattern 804 can be used in conjunction with a camera 806 to capture three-dimensional (3D) images by analyzing the change or distortion in the structured light pattern by objects located at different distances.

In the example of FIG. 8, the VCSEL beams are emitted perpendicular to the VCSEL plane and, thus, the diameter of the projection lens 810 should be large enough to pass the VCSEL beams. If the beam has high divergence, then the lens diameter needs to be even larger to capture the entire beam. By reducing the VCSEL beam divergence, a smaller diameter lens 810 can be used in some cases. Smaller components can be important for producing miniature projectors for smart phones and other compact portable devices.

As the projected pattern 804 is used to capture 3D images, the depth of focus of the VCSEL image should be sufficiently large so that the pattern maintains its structure over a relatively long distance. The depth of focus depends on the beam divergence. If the beam divergence is large, the depth of focus will be short because adjacent spots in the pattern 804 will overlap at locations away from the focus position. For beams with low divergence, the distance before the beams overlap will be larger, thereby increasing the depth of focus.

The system 800 also includes multiple electrical contacts operable to direct electric current to the array 802 of narrow beam divergence semiconductor sources.

Although the foregoing example includes an array of VCSELs (e.g., as described in connection with any of FIGS. 1-3), the array may be composed of other types of narrow beam divergence semiconductor sources (e.g., VECSELs, LEDs, LC-LEDs, edge-emitting devices) as described above in connection with FIGS. 4, 5, 6, 7.

Various modifications can be made to the foregoing examples. Further, various features may be omitted in some implementations, while other features may be added. Features described in connection with different embodiments may, in appropriate instances, be combined in a single implementation. Thus, other implementations are within the scope of the claims.

1. A structured light projector comprising:
an array of narrow beam divergence semiconductor sources, each narrow beam divergence semiconductor source within the array being operable to generate a beam with a substantially narrow beam divergence and substantially uniform beam intensity;
a plurality of electrical contacts operable to direct electric current to the array of narrow beam divergence semiconductor sources; and
a projection lens operable to generate an image of the array of narrow beam divergence semiconductor source.

2. The structured light projector of claim 1, wherein each narrow beam divergence semiconductor source within the array of sources includes:
an optical resonant cavity including a high reflection mirror having first and second sides, an extended length mirror having first and second sides, and an active region;
the high reflection mirror and the extended length mirror being disposed on distal sides of the active region such that the first side of the high reflection mirror is coupled to a first side of the active region, and the first side of the extended length mirror is coupled to a second side of the active region opposing the first;
the beam being having an emission wavelength; and
the plurality of electrical contacts being operable to direct electric current to the active region.

3. The structured light projector of claim 2, wherein the extended length mirror and the high reflection mirror within each narrow beam divergence semiconductor source are operable to suppress one or more longitudinal and/or transverse modes such that one or more longitudinal and/or transverse modes lase.

4. The structured light projector of claim 3, wherein the extended length mirror and the high reflection mirror within each narrow beam divergence semiconductor source are operable such that only one longitudinal mode lases.

5. The structured light projector of claim 2, wherein the extended length mirror within each narrow beam divergence semiconductor source has:
an effective penetration depth, the effective penetration depth extending a plurality of emission wavelength distances from the first side of the extended length mirror; and
a relative refractive index difference.

6.-11. (canceled)

12. The structured light projector of claim 1, wherein any one of the narrow beam divergence semiconductor sources are operable as any one of a VCSEL;
RC-LED; or
an LED.

13.-14. (canceled)

15. The structured light projector of claim 2, wherein the high reflection mirror of any of the narrow beam divergence semiconductor sources further include a supplemental extended length mirror with a first side substantially coincident with the first side of the high reflection mirror, the supplemental extended length mirror having an effective penetration depth, the effective penetration depth extending a plurality of emission wavelength distances from the first side of the supplemental extended length mirror, the supplemental extended length mirror having a relative refractive index difference.

16. The structured light projector of claim 1, wherein the narrow beam divergence semiconductor sources are arranged in a non-regular layout with respect to each other.

17.-19. (canceled)

20. The structured light projector of claim 2, wherein the extended length mirror of any of the narrow beam divergence semiconductor sources comprises two or more reflection elements arranged to reduce the wavelength linewidth of the reflection such that one or more longitudinal and/or transverse modes are suppressed and one or more longitudinal and/or transverse modes lase.

21. (canceled)

22. The structured light projector of claim 2, wherein the extended length mirror of any of the narrow beam divergence semiconductor sources comprises a hybrid DBR including a high-contrast region and a low-contrast region, wherein the high-contrast region includes a plurality of DBR pairs using materials with high refractive index difference, the DBR pairs being periodically disposed within the high-contrast region, and wherein the low-contrast region includes a plurality DBR pairs using materials with low refractive index difference, the low-contrast pairs being periodically disposed within the low-contrast region.

23. (canceled)

24. The structured light projector of claim 2, wherein any of the narrow beam divergence semiconductor sources further includes an oxide aperture, the oxide aperture being operable to increase the current density in the active region.

25. The structured light projector of claim 2, wherein any of the narrow beam divergence semiconductor sources further includes an emission mirror and a backside mirror disposed on opposing sides of the narrow beam divergence semiconductor source, the backside mirror having higher reflectivity than the emission mirror.

26. The structured light projector of claim 25, wherein:
the backside mirror includes the extended length mirror and the emission mirror includes the high reflection mirror; or
the backside mirror includes the high reflection mirror and the emission mirror includes the extended length mirror.

27. (canceled)

28. The structured light projector of claim 22, wherein the DBR and/or the hybrid DBR of any of the narrow beam divergence semiconductor sources are operable, together with the plurality of electrical contacts, to direct electric current to the active region.

29. The structured light projector of claim 22, wherein any of the narrow beam divergence semiconductor sources further include one or more phase-matching layers between the hybrid mirror components.

30. The structured light projector of claim 22, wherein the first charge-carrier type is p-type semiconductor and the second charge-carrier type is n-type semiconductor.

31. The structured light projector of claim 22, wherein the high-contrast region of the hybrid DBR and the low-contrast region of the hybrid DBR of any of the narrow beam divergence semiconductor sources are interposed by a substrate of a second charge-carrier type.

32. A structured light projector comprising:
an array of narrow beam divergence semiconductor optical edge-emitting laser sources, each narrow beam divergence semiconductor optical edge-emitting laser source within the array being operable to generate a beam with a substantially narrow beam divergence and substantially uniform beam intensity;
a plurality of electrical contacts being operable to direct electric current to the array of narrow beam divergence semiconductor optical edge-emitting laser sources; and
a projection lens operable to generate an image of the array of narrow beam divergence semiconductor optical edge-emitting laser source.

33. The structured light projector of claim 32, wherein each narrow beam divergence semiconductor optical edge-emitting laser source within the array of sources includes:
a hybrid distributed Bragg reflector (hybrid DBR), the hybrid DBR having first and second sides, the edge-emitting laser being disposed on the first side of the hybrid DBR;
the hybrid DBR including a high-contrast region and a low-contrast region, wherein the high-contrast region includes a plurality of high refractive index difference pairs of a DBR materials of a second charge-carrier type, the high-contrast pairs being periodically disposed within the high-contrast region, and wherein the low-contrast region includes a plurality of pairs of a low refractive index difference DBR materials of the second charge-carrier type, the low-contrast pairs being periodically disposed within the low-contrast region; and
the hybrid DBR and the edge-emitting laser being operable to generate an emission having a spectral width of emission and a beam divergence; and the edge-emitting laser and the hybrid DBR having a narrow spectral bandwidth, the narrow spectral bandwidth being operable to substantially suppress one or more transverse and/or longitudinal modes such that the beam divergence and/or the spectral width of emission is substantially reduced.

34. The structured light projector of claim 33, wherein
the hybrid DBR of any of the narrow beam divergence semiconductor optical edge-emitting laser sources further includes a phase-matching layer disposed between the high-contrast region and the low-contrast region; or
the hybrid DBR further DBR of any of the narrow beam divergence semiconductor optical edge-emitting laser sources includes a backside dielectric coating disposed on the second side of the hybrid DBR.

35. (canceled)
